(19) United States
(12) Patent Application Publication
(10) Pub. No.: US 2010/0315161 A1
(43) Pub. Date: Dec. 16, 2010

(54) Power Inductor

(75) Inventors: Igor Morozov, Fort Collins, CO (US); Natasha Morozov, Masonville, CO (US)

Correspondence Address: Neugeboren O'Dowd PC, 1227 Spruce Street, SUITE 200, BOULDER, CO, 80302, US

(73) Assignee: ADVANCED ENERGY INDUSTRIES, INC., Fort Collins, CO (US)

(21) Appl. No.: 12/485,175

(22) Filed: Jun. 16, 2009

(51) Int. Cl. H01F 27/10; H03F 3/68; H02J 4/00

(52) U.S. Cl. 330/124 R; 336/60; 307/84

(57) ABSTRACT

A power inductor comprising a tube and one or more coils. The tube in one embodiment is generally cylindrical and comprises a liquid-cooled center portion, the tube further comprising an inner diameter, an outer diameter, and an outer surface. The coils of one embodiment are coupled to the tube outer surface, with each of the one or more coils having a coil thickness, and at least a portion of a coil turn.

### FIELD OF THE INVENTION

The present invention generally relates to power inductors. In particular, but not by way of limitation, the present invention relates to applications involving liquid-cooled power inductor tubes.

### BACKGROUND OF THE INVENTION

Power systems such as, but not limited to, generators and amplifiers contain power inductors in order to properly transmit and store generated power. Inductors are electrical components that store energy in a magnetic field created by an electrical current passing through the inductor. Typically formed of metal coils, inductors have an inherent resistance from the metal wire forming the coils. The resistance converts the electrical current into heat. The conversion of electrical energy to thermal energy causes a loss of power system electrical output. This power loss may reach 10-15% of the power received by the inductor, thus significantly reducing overall efficiency of the power system.

Each inductor possesses a quality factor, or “Q”. Generally, an inductor's Q value comprises a number inversely proportional to the power that is loss by the inductor. So, an inductor with a high Q value generally correlates to an inductor having low power loss. Therefore, inductors that generate large amounts of heat typically have lower Q values than inductors that generate less heat at similar frequencies and power. Therefore, inductors are typically cooled in order to increase an inductor's Q value.

A popular approach to cooling inductors is to create a “dinner plate” inductor. A dinner plate inductor typically comprises spiral inductor coils printed on a ceramic plate. The ceramic plate is then attached to a cold plate with a thermal grease. Heat dissipation and Q value depend on the ability of the cold plate to dissipate heat in the inductor coils.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

One embodiment of the invention comprises a power inductor having a generally cylindrical liquid-cooled tube and one or more coils coupled to the tube. One tube may be comprised of an inner diameter, an outer diameter, and a tube outer surface, with the one or more coils being coupled to the tube outer surface. Each of the one or more coils of one embodiment has a coil thickness, a number of coil turns, and a longitudinal spacing between coil turns.

Another embodiment of the invention comprises a power generator having one or more power amplifiers, one or more generally helically-shaped coils, and an output. In one embodiment each of the one or more power amplifiers are adapted to emit a first electrical signal and each of the one or more generally helically-shaped coils are electronically coupled to and adapted to receive the first electrical signal from at least one of the one or more power amplifiers. The one or more coils may also be parallelly-aligned and adapted to be cooled by at least one tube. Furthermore, the output may be electronically coupled to at least one of the one or more coils and adapted to emit an electrical signal, the electrical signal being comprised of one or more electrical signals received from the at least one of the one or more coils.

Yet another embodiment of the invention comprises a power generation system. One power generation system comprises a plurality of power sources, with each power source adapted to produce a first electrical signal. One power generation system is also comprised of an insulator device having a liquid-cooled center and a plurality of inductor coils coupled to the inductor device. Each of the plurality of coils is electrically coupled to and adapted to receive at least one first electrical signal from at least one of the plurality of power sources. One power generation system also comprises a cold plate that is coupled to a section of the liquid-cooled tube.

These and other embodiments are described in further detail herein.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings, wherein:

FIG. 1 is an isometric view of one inductor in accordance with an illustrative embodiment of the invention.

FIG. 2 is a functional top view of a portion of a power generator in accordance with an illustrative embodiment of the invention.

FIG. 3A is a functional top view of a portion power system in accordance with an illustrative embodiment of the invention.

FIG. 3B is a cross-sectional view of an insulator device and a cold plate along line A-A shown in FIG. 3A in accordance with an illustrative embodiment of the invention.

### DETAILED DESCRIPTION

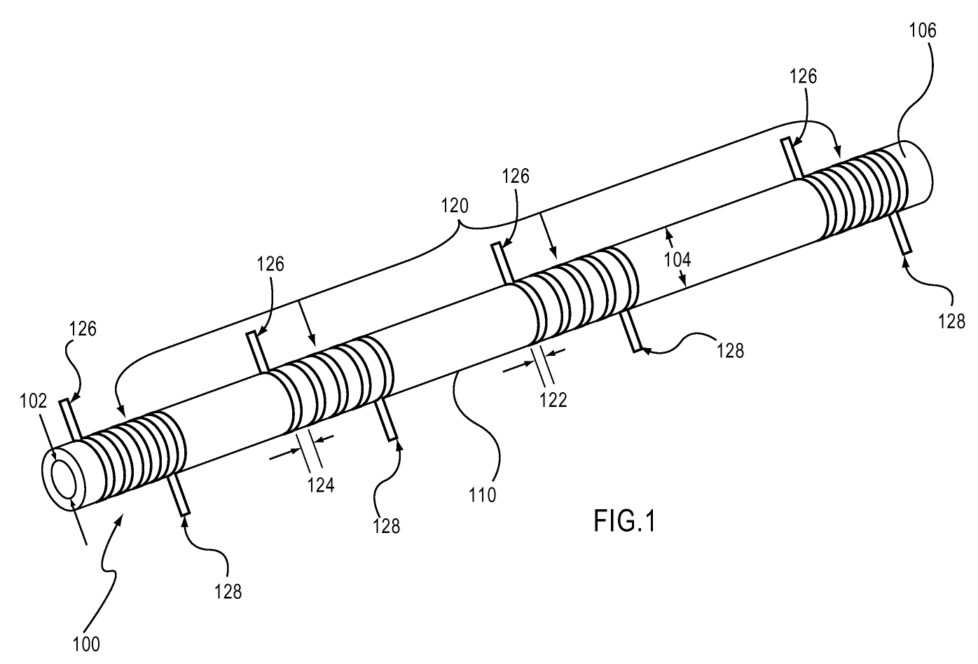

Referring now to the drawings, where like or similar elements are designated with identical reference numerals throughout the several views where appropriate, and referring in particular to FIG. 1, shown is a power inductor 100. One power inductor 100 is comprised of a tube 110 and one or more inductor coils 120. A tube 110 having four inductor coils 120 is shown in FIG. 1. The tube 110 in one embodiment comprises a first material having a generally cylindrical shape. However, alternative tube 110 shapes such as, but not limited to rectangularly-shaped tube 110 cross-sections are also contemplated, as well as other shapes adapted for efficient inductor 100 operation. For example, other tube 110 shapes may provide for a larger surface area to contact the inductor coils 120 so that the cooling of the coils 120 is maximized. In one embodiment, the inductor coils 120 are comprised of a second material.

Aspects of the power inductor 100 include an inductor tube 110 with an inner diameter 102, an outer diameter 104, and an outer surface 106. One inner diameter 102 may be about ¼″ and one outer diameter 104 may be about ½″ in one embodiment. Furthermore, the one or more inductor coils 120 in one embodiment may be coupled to the tube outer surface 106, with each of the one or more coils 120 comprising a coil thickness 122, and at least a portion of a coil turn. For example, inductors are contemplated which comprise less than a full coil turn, and inductors are contemplated which comprise a plurality of coil turns, with the FIG. 1 inductor having coils 120 comprising five coil turns. In embodiments having coils 120 with more than a single coil turn, the inductor 100 further comprises a longitudinal spacing 124 between each turn.

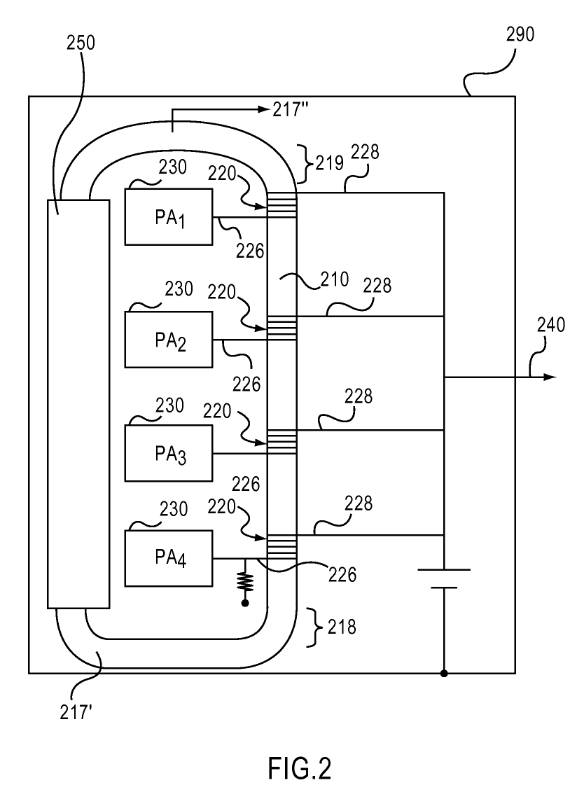

In one embodiment, each of the coils 120 may also be comprised of an input portion 126 and an output portion 128. The input portion 126 may be adapted to receive a first electrical signal from a power source such as, but not limited to, a power amplifier 230, as shown in FIG. 2. At least one power source may be serially coupled to at least one coil 120. The coil output portion 128 may be adapted to send a second electrical signal to an output 240, also as shown in FIG. 2. In order for the coils 120 to properly operate with the first electrical signal, at least one of the coil thickness 122, the number of coil turns, and the longitudinal spacing 124 between the coil turns may be modified. For example, in order to properly operate with one of a higher and a lower electrical signal wattage received from a power amplifier 230, or with a different signal frequency, the number of turns may be increased or decreased or a specific coil material may be used.

In one embodiment, the first material may comprise an insulator material. For example, the tube 110 may be comprised of a ceramic composite. However, other insulator materials are also contemplated. One embodiment's coils 120 are comprised of a second material. One second material may comprise a conductive material such as, but not limited to a copper alloy and/or a silver alloy. The conductive material may be coupled to the insulator material by first creating a conductive material paste and/or applying the conductive material to the insulator material as a ribbon. Although in one embodiment, the conductive material may be applied to the outer surface 106 of the tube 110, it is contemplated that the conductive material may also be applied to an etched or bored section of the tube 110. Other methods known in the art of coupling the conductive material to the inductive material are also contemplated.

As also shown in FIG. 2, one embodiment of an inductor 100 comprises a tube 110 adapted to couple to a cold plate 250. The cold plate 250 in one embodiment may be adapted to cool a liquid that flows through the tube 110. For example, the liquid may enter a hollow tube section which may comprise a tube center portion. The water may flow through the tube center portion and subsequently exit from the tube 110.

Turning our attention now to FIG. 2, shown is a power generator 290. One embodiment of a power generator 290 comprises one or more power amplifiers 230, one or more generally helically-shaped coils 220, and an output 240. Each of the one or more power amplifiers 230 is adapted to emit a first electrical signal. Furthermore, in one embodiment, each of the one or more generally helically-shaped coils 220 is electronically coupled to and adapted to receive the first electrical signal from at least one of the one or more power amplifiers 230. The coils may comprise an input portion 226 to receive the first electrical signal and an output portion 228 to emit a second electrical signal. Also, the coils may be cooled by at least one tube 210. The output 240 is electronically coupled to the output portion 228 of at least one of the one or more coils 220, and is adapted to receive the second electrical signal from the at least one of the one or more coils 220. The output 240 is thereinafter adapted to emit a third electrical signal, the third electrical signal being comprised of one or more second electrical signals.

As seen in FIG. 2, in one embodiment the one or more coils 220 comprise four parallely-aligned coils 220. The tube 210 which may be used in one embodiment to cool the coils 220 may comprise a plurality of tubes 210, each tube 210 adapted to cool at least a portion of one coil 220. For example, in one embodiment, each coil 220 may be cooled by a separate tube 210. In one embodiment the one or more tubes 210 are comprised of a single ceramic liquid-cooled tube 210 that is coupled to the cold plate 250. The tube 210 may be adapted to receive a cooling liquid such as, but not limited to, water, from a cold plate 250 through a proximal cold plate connector 217′, receiving the liquid at a tube proximal end 218. The cooling liquid may travel through the tube 100 to the tube distal end 219, cooling the tube and one or more coils 120 that are coupled to the tube 210 along the way. Upon reaching the tube distal end 219, the cooling liquid may exit the tube 100 and travel back to the cold plate 250 or other device through a distal cold plate connector 17″.

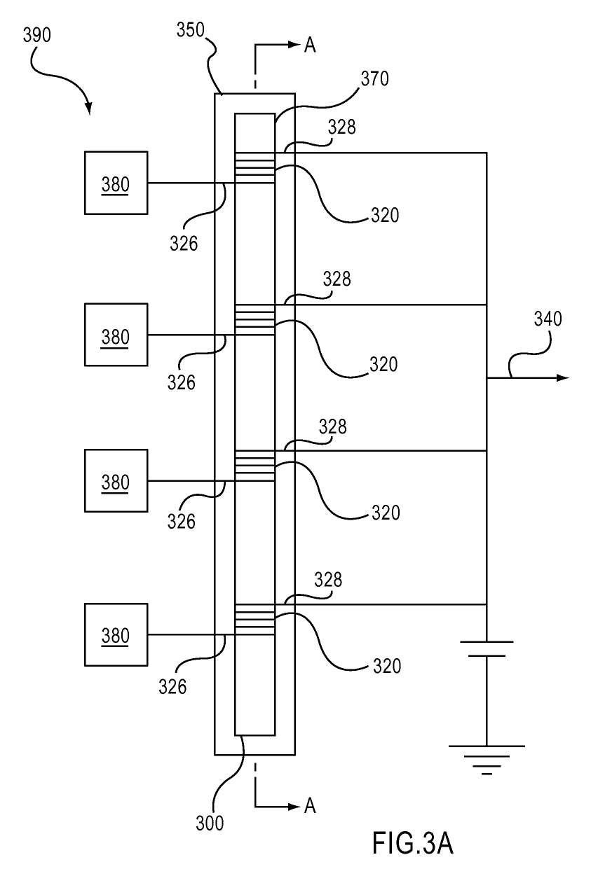

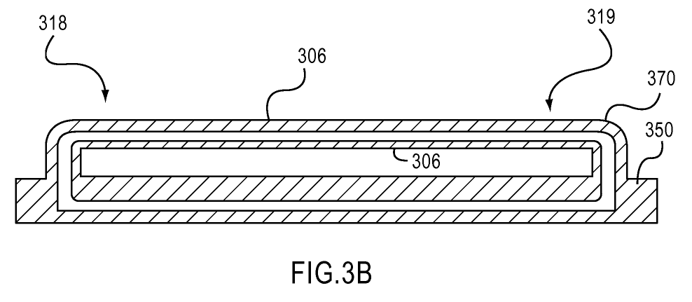

In now looking at FIG. 3A, shown is a power generation system 390. One power generation system 390 comprises a plurality of power sources 380 adapted to emit a first electrical signal, an insulator device 370, a plurality of inductor coils 320, and a cold plate 350. The plurality of inductor coils 320 are electrically coupled to and adapted to receive at least one first electrical signal from at least one power source 380. Additionally, the inductor coils 320 are coupled to the insulator device 370. The insulator device 370 in one embodiment is comprised of a tube having an insulator material, the insulator device 370 being adapted to receive a liquid, with the liquid being adapted to cool the insulator material and the inductor coils 320. Furthermore, the inductor coils 320 may be coupled to the tube in a manner such that the coils 320 are not in contact with the liquid when received by the insulator device 370. Finally, the cold plate 350 in one embodiment of a power generation system 390 is adapted to help cool the insulator device 370.

As seen in FIG. 3B, one embodiment may comprise an insulator device 370 comprising a tube that is integrated to the cold plate 350. In other embodiments, the tube may couple to the cold plate 350. In either embodiment, a liquid such as, but not limited to, water, may enter the cold plate 350 and subsequently travel from the cold plate 350 to a proximal end 319 of the insulator device 370, lowering a temperature of the outer surface 306 of the insulator device 370 through thermal conduction. In cooling the outer surface 306 of the insulator device 370, the temperature of the inductor coils 320 which are coupled to the outer surface 306 of the insulator device 370 are also kept at a lower temperature, thereby reducing the coils' 320 power loss and increasing the Q rating for the power inductor 370. In other embodiments, the coils 320 may be coupled to a portion of the insulator device 370 other than the outer surface 306. For example, the insulator device 370 may comprise one or more etched areas or bores adapted to receive an inductor coil 320. The water may then exit the insulator device 370 at the distal end 319. Upon exiting the tube, the water may re-enter the cold plate 380 or the water may travel to a separate cooling system to return the water to a lower temperature prior to entering the proximal end 318.

The insulator material in one embodiment may be comprised of a ceramic. However, other materials are also contemplated such as other materials having insulator properties that are similar to the insulator properties of ceramic. Furthermore, in one embodiment, the insulator device 370 is comprised of a proximal end 318 and a distal end 319. In one embodiment, the inductor coils 320 may comprise generally helically-shaped inductor coils.

Each power source 380 shown in FIG. 3A may comprise one or more power generators in one embodiment. It is to be appreciated that each power source 380 may comprise any source of electrical power.

Also included in one power generation system 390 may be an output 340. An induction coil input portion 326 may receive a first signal from a serially-aligned power source 380 and emit a second signal at the induction coil output portion 328. As the induction coils 320 are parallelly aligned in one embodiment, the output 340 is adapted to receive the second signal emitted from each of the plurality of parallel aligned induction coils and subsequently emit a output signal.

What is claimed is:

1. A power inductor comprising,
a generally cylindrical liquid-cooled tube having an inner diameter, an outer diameter, and an outer surface; and
one or more coils coupled to the tube outer surface, each of the one or more coils having a coil thickness, and at least a portion of a coil turn.

2. The power inductor of claim 1 wherein,
the at least a portion of a coil turn comprises a plurality of coil turns; and
the one or more coils further comprise a longitudinal spacing between the plurality of coil turns.

3. The power inductor of claim 1 wherein,
the inner diameter comprises a length of about ¼ inch; and
the outer diameter comprising a length of about a ½ inch.

4. The power inductor of claim 1 wherein,
the tube comprises a first material; and
the one or more coils comprise a second material.

5. The power inductor of claim 4 wherein,
the first material comprises an insulator material; and
the second material comprises a conductor material.

6. The power inductor of claim 2 wherein,
each of one or more coils are adapted to receive a first electrical signal and emit a second electrical signal.

7. The power inductor of claim 6 wherein,
at least one of the coil thickness, the plurality of coil turns, and the longitudinal spacing between the plurality of coil turns is adapted to be modified in order for the inductor to one of receive the first electrical signal and emit the second electrical signal.

8. The power inductor of claim 6 wherein, the first electrical signal comprises a signal emitted from one or more power sources, each of the one or more power sources being serially coupled to a coil.

9. The power inductor of claim 1 wherein, the tube is adapted to couple to a cold plate.

10. The power inductor of claim 1 wherein, the one or more coils are further comprised of input portion and an output portion.

11. A power generator comprising,
one or more power amplifiers, each of the one or more power amplifiers adapted to emit a first electrical signal;
a plurality of generally helically-shaped coils,
each of the plurality of generally helically-shaped coils electronically coupled to, and adapted to receive, the first electrical signal from at least one of the one or more power amplifiers,
the plurality of coils being parallelly-aligned and adapted to be cooled by at least one tube; and
an output electronically coupled to the plurality of coils, the output adapted to emit a third electrical signal.

12. The power generator of claim 11 wherein, the at least one tube comprise a single ceramic liquid-cooled tube coupled to a cold plate.

13. The power generator of claim 11 wherein,
the at least one tube comprises an outer surface; and
the one or more generally helically-shaped coils are adapted to be applied to the outer surface as a paste.

14. The power generator of claim 11 wherein, the one or more generally helically-shaped coils comprise a first material and at least one coil turn adapted to operate with the first electrical signal.

15. A power generation system comprising,
a plurality of power sources, each power source adapted to produce a first electrical signal;
a power inductor comprising,
an insulator device having a liquid-cooled center;
a plurality of inductor coils, each inductor coil being (i) electrically coupled to and adapted to receive at least one first electrical signal from at least one power source,
and (ii) coupled to the insulator device; and
a cold plate adapted to cool the insulator device.

16. The power generation system of claim 15 wherein, the insulator device,
comprises a ceramic tube having a proximal end, a distal end, and an area adapted to receive the plurality of inductor coils; and
is adapted to receive a stream of water at the proximal end and exit the stream of water at the distal end, the stream of water being adapted to cool the insulator device.

17. The power generation system of claim 15 wherein the insulator device further comprises at least one of an outer surface and an etched area adapted to receive the plurality of generally helically-shaped coils.

18. The power generation system of claim 15, wherein, the plurality of power sources comprise a plurality of power generators.

19. The power generation system of claim 15 further comprising an output.

20. The power generation system of claim 19 wherein, the plurality of coils are parallelly aligned.
